(19) United States
(12) Patent Application Publication
(10) Pub. No.: US 2009/0091255 A1
(43) Pub. Date: Apr. 9, 2009

(54) White organic light emitting device

(76) Inventors: Sung-Hoon Lee, Seoul (KR); Sang-Yeol Kim, Gwacheon-si (KR); Mu-Gyeom Kim, Hwaseong-si (KR); Jung-Bae Song, Seongnam-si (KR)

Correspondence Address: ROBERT E. BUSHNELL & LAW FIRM, 2029 K STREET NW, SUITE 600, WASHINGTON, DC, 20006-1004, US

(21) Appl. No.: 12/285,559

(22) Filed: Oct. 8, 2008

(30) Foreign Application Priority Data
Oct. 9, 2007 (KR) 10-2007-0101668
May 19, 2008 (KR) 10-2008-0046292

(51) Int. Cl. H01J 1/62

(52) U.S. Cl. 313/504

(57) ABSTRACT

A white organic light emitting device (OLED) includes an anode, a first phosphorescent layer including a first host material and a first dopant disposed on the anode, a blue fluorescence layer including a blue host material and a blue dopant disposed on the first phosphorescent layer, and a second phosphorescent layer including a second host material and a second dopant disposed on the blue fluorescence layer. In addition, a triplet energy of the blue host material of the blue fluorescence layer is greater than both of a triplet energy of the first dopant of the first phosphorescent layer and a triplet energy of the second dopant of the second phosphorescent layer.

### CLAIM OF PRIORITY

This application makes reference to, incorporates the same herein, and claims all benefits accruing under 35 U.S.C. §119 from applications earlier filed in the Korean Intellectual Property Office on Oct. 9, 2007 and there duly assigned Serial No. 10-2007-0101668, and on May 19, 2008 and there duly assigned Serial No. 10-2008-0046292, respectively.

### BACKGROUND OF THE INVENTION

1. Field of the Invention

The exemplary embodiment relates to a white organic light emitting device, and more particularly, to a white organic light emitting device in which triplet excitons are dispersed from a fluorescent emitting layer to an emitting layer without energy transition, and thus has an excellent light emitting efficiency.

2. Description of the Related Art

Organic light emitting devices (OLEDs) are light emitting devices in which holes supplied from an anode and electrons supplied from a cathode are combined in an organic light emitting layer that is formed between the anode and the cathode to emit the light. OLEDs can be used in television monitors, monitors for personal computers, mobile terminals, MP3 players, navigators, and indoor and outdoor illuminations or signs, due to characteristics such as excellent color reproductivity, rapid response speed, self emission, small thickness, high contrast, wide viewing angle, and low power consumption.

White OLEDs are OLEDs that emit white light, and can be applied as thin light sources, backlights for liquid crystal displays (LCDs), or full color display devices by using a color filter.

Light emission from OLEDs has typically been via fluorescence, however OLED emission via phosphorescence has been recently demonstrated. As used herein, the term “phosphorescence” refers to emission from a triplet excited state of an organic molecule and the term “fluorescence” refers to emission from a singlet excited state of an organic molecule. In quantum mechanics, a triplet state is a state of a system that has a total spin angular momentum of one; and a singlet state is a state of a system that has a total spin angular momentum of zero.

In order to improve the light emission efficiency of white OLEDs, a structure that can achieve an internal quantum efficiency of nearly 100%, is required. To form such a structure, research has recently been conducted into using a phosphorescent material as a light emitting layer. In a fluorescent material, a singlet energy occupying about 25% of all excitons is radiatively transited while the remaining 75% ofthe energy is lost due to a non-emissive transition. In a phosphorescent material, however, triplet excitons generate radiative transition, and thus, high light emission efficiency can be achieved by appropriately using the phosphorescent material.

### SUMMARY OF THE INVENTION

It is therefore an object of the present invention to provide an improved white OLED structure.

It is another object of the present invention to provide a white OLED having a structure that can allow a triplet energy to be diffused from a fluorescent layer to a phosphorescent layer without an energy transition.

According to an aspect of the exemplary embodiment, a white organic light emitting device (OLED) is provided with a first phosphorescent layer including a first host material and a first dopant, a blue fluorescence layer including a blue host material and a blue dopant and disposed on the first phosphorescent layer, and a second phosphorescent layer including a second host material and a second dopant and disposed on the blue fluorescence layer.

A triplet energy of the blue host material of the blue fluorescence layer may be greater than a triplet energy of the first dopant of the first phosphorescent layer and a triplet energy of the second dopant of the second phosphorescent layer.

The first host material of the first phosphorescent layer may have a hole transport-property. The second host material of the second phosphorescent layer may have an electron transport property.

The white OLED may further include a first functional layer which is disposed between the blue fluorescence layer and the first phosphorescent layer, and which has a band gap energy that is greater than that of the blue dopant of the blue fluorescence layer, and a triplet energy level that is equal to or lower than that of the blue host material of the blue fluorescence layer and that is equal to or higher than that of the first dopant of the first phosphorescent layer.

The white OLED may further include a second functional layer, which is formed between the blue fluorescence layer and the second phosphorescent layer, and which has a band gap energy that is greater than that of the blue dopant of the blue fluorescence layer and a triplet energy level that is equal to or lower than that of the blue host material of the blue fluorescence layer and that is equal to or higher than that of the second dopant of the second phosphorescent layer.

The second functional layer may have a highest occupied molecular orbital (HOMO) energy level ranging from 5.5 eV to 7.0 eV, and a lowest unoccupied molecular orbital (LUMO) energy level ranging from 2.5 eV to 3.5 eV.

The first and second functional layers may have wide band gaps within a range that does not absorb the light emission spectrum of the blue dopant on the blue fluorescent layer.

The first functional layer may have a HOMO energy level ranging from 5.2 eV to 6.2 eV, and a LUMO energy level ranging from 2.0 eV to 3.0 eV. The second functional layer may have a HOMO energy level ranging from 5.5 to 7.0 eV, and a LUMO energy level ranging from 2.5 to 3.5 eV.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a schematic cross-sectional view of an OLED constructed as a first exemplary embodiment according to the principles of the present invention;

FIG. 2 is a schematic cross-sectional view of an OLED constructed as a second exemplary embodiment according to the principles of the present invention;

FIG. 3 is a graph showing light emitting spectrums of a contemporary white OLED having a fluorescent layer-fluorescent layer-phosphorescent layer (FFP) structure and a white OLED having a phosphorescent layer-fluorescent layer-phosphorescent layer (PFP) structure constructed as an exemplary embodiment according to the principles of the present invention;

FIG. 4 is a graph showing light emitting spectrums at varying brightness of a white OLED (PFP structure) constructed as an embodiment of the exemplary embodiment according to the principles of the present invention;

FIG. 5 is a graph showing a CIE 1931 color space chromaticity diagram.

### DETAILED DESCRIPTION OF THE INVENTION

Exemplary embodiments will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals refer to like elements.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

It will be understood that, although the terms first, second, third and other counters may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed as a second element, component, region, layer or section without departing from the teachings of the exemplary embodiment.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Example embodiments are described herein with reference to cross section illustrations that are schematic illustrations of idealized embodiments of the exemplary embodiment. As such, variations from the shapes of the illustrations as a result, for example, of manufacturing techniques and/or tolerances, are to be expected. Thus, embodiments of the exemplary embodiment should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the exemplary embodiment.

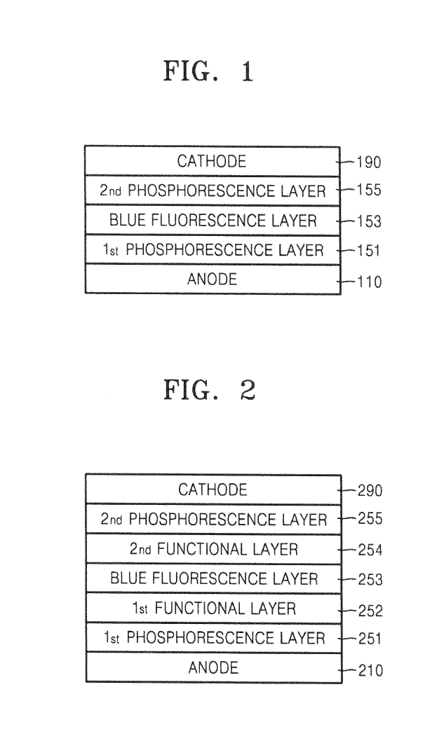

FIG. 1 is a schematic cross-sectional view of an OLED constructed as a first exemplary embodiment according to the principles of the present invention. Referring to FIG. 1, the OLED of the first exemplary embodiment has a structure in which a first phosphorescent layer 151, a blue fluorescent layer 153, a second phosphorescent layer 155, and a cathode 190 are sequentially stacked in this order on an anode 110. Anode 110 may be formed on an insulating substrate (not shown) such as a glass substrate or a plastic substrate.

Anode 110 can be made from a transparent material having a high electrical conductivity and a high work function. For example, if the OLED is a bottom emission type OLED, anode 110 can be made from indium tin oxide (ITO), indium zinc oxide (IZO), SnO₂, or ZnO. Meanwhile, if the OLED is a top emission type OLED, anode 110 may be a reflective electrode made from metal.

First phosphorescent layer 151, blue fluorescent layer 153, and second phosphorescent layer 155 can be sequentially formed on anode 110 in this order. A host material of blue fluorescent layer 153 has a greater triplet energy than that of dopants in first phosphorescent layer 151 and second phosphorescent layer 155. In quantum mechanics, a triplet state is a state of a system that has a total spin angular momentum of one; and a singlet state is a state of a system that has a total spin angular momentum of zero. The triplet energy is the difference between an energy of the system in the triplet state and an energy of the system in the singlet state. Besides including the host material having the high triplet energy, blue fluorescent layer 153 includes a blue fluorescent material as a dopant. Here, the host material of blue fluorescent layer 153 may be any material that is used in an OLED, for example, 9,10-di-(2-naphthyl)anthracene (AND), tertiary butyl AND (TBADN), carbazole biphenyl (CBP), 4,4′,4″-Tris-(carbazol-9-yl)-triphenylamine (TCTA), or a tris-8-quinolinolate aluminum complex (Alq₃). In addition, the blue fluorescent dopant is not limited in particular, and 4,4′-bis[2-{4-(N,N-diphenylamino)phenyl}vinyl]biphenyl (DPAVBi), DPAVBi derivatives, distyrylarylene (DSA), DSA derivatives, distyrylbenzene (DSB), DSB derivatives, spiro-DPVBi, biphenyltetracarboxylic acid (BPTA), BPTA derivatives, or spiro-6P may be used as the blue fluorescent dopant.

First phosphorescent layer 151 and second phosphorescent layer 155 may have host materials that are the same as that of blue fluorescent layer 153. Dopants in first phosphorescent layer 151 and second phosphorescent layer 155 are phosphorescent materials, and may have lower triplet energy than that of the host material of blue fluorescent layer 153. On the other hand, host materials of first and second phosphorescent layers 151 and 155 may have hole transport characteristics and electron transport characteristics, respectively, in order to maximize the amount of excitons of blue fluorescent layer 153. Phosphorescent materials that can be used as the dopants in first and second phosphorescent layers 151 and 155 are not limited in particular. For example, 3-(2′-benzothiazolyl)-7-diethylaminocoumarin (known as Coumarin 6 or C6), or 10-(2-benzothiazolyl)-1,1,7,7-tetramethyl-2,3,6,7-tetrahydro-1H,5H,11H-[1]benzopyrano[6,7,8-ij]quinolizin-11-one (known as Coumarin 545T or C545T), or Ir(PPy)3(PPy=2-phenylpyridine) may be used as a green dopant; and [4-(dicyanomethylene)-2-t-butyl-6-(1,1,7,7-tetramethyljulolidyl-9-enyl)-4H-pyran(4-(dicyanomethylene)-2-t-butyl-6-(1,1,7,7-tetramethyljulolidyl-9-enyl)-4H-pyran;DCJTB)], Alq with 6% of 2,3,7,8,12,13,17,18-octaethyl-21H,23H-porphyrin-platinum (PtOEP), RD 61 and RD15 (available from UDC Corp.), or TER021 (available from Merck Corp), may be used as a red dopant.

The triplet excitons generated in the host of blue fluorescent layer 153 are diffused in both side directions so as to generate a radiative transition or recombination in the phosphorescent dopants of first phosphorescent layer 151 and second phosphorescent layer 155. Therefore, if each of first and second phosphorescent layers 151 and 155 includes the red or green dopant described above, a white OLED having high light emission efficiency can be obtained.

Cathode 190 can be formed on second phosphorescent layer 155. Cathode 190 may be formed using a vacuum deposition method or a sputtering method. Cathode 190 can be made from a metal, an alloy, an electrical compound having a small work function, or a mixture thereof. For example, cathode 190 can be made from Li, Mg, Al, Al—Li, Ca, Mg—In, or Mg—Ag. If the OLED is a top emission type OLED, cathode 190 can be made from a transparent conductive material such as ITO or IZO that has a high electrical conductivity and a high work function.

A hole transport layer (not shown) or an electron blocking layer (not shown) maybe further formed between anode 110 and first phosphorescent layer 151. In addition, an electron transport layer (not shown) or a hole blocking layer (not shown) may be further formed between cathode 190 and second phosphorescent layer 155.

FIG. 2 is a schematic cross-sectional view of an OLED constructed as a second exemplary embodiment according to the principles of the present invention. Hereinafter, elements that are different from those of the first exemplary embodiment will be described.

Referring to FIG. 2, the OLED of the second exemplary embodiment has a structure in which a first phosphorescent layer 251, a first functional layer 252, a blue fluorescent layer 253, a second functional layer 254, a second phosphorescent layer 255, and a cathode 290 are sequentially stacked in this order on an anode 210. Here, anode 210, first phosphorescent layer 251, blue fluorescent layer 253, second phosphorescent layer 255, and cathode 290 are the same as anode 110, first phosphorescent layer 151, blue fluorescent layer 153, second phosphorescent layer 155, and cathode 190 of the first exemplary embodiment, respectively, and thus, detailed descriptions thereof are not provided here.

In the second exemplary embodiment, first functional layer 252 that can prevent Foster energy transfer (hereinafter, referred to as energy transfer) without interfering with the diffusion of triplet excitons between the light emitting layers may be formed between first phosphorescent layer 251 and blue fluorescent layer 253. A donor chromophore in its excited state can transfer energy by a nonradiative, long-range dipole-dipole coupling mechanism to an acceptor chromophore in close proximity (typically <10 nm). This energy transfer mechanism is termed Förster resonance energy transfer.

Here, first functional layer 252 has a greater band gap energy than that of the dopant in blue fluorescent layer 253, and has a triplet energy equal to or less than that of the host of blue fluorescent layer 253 and equal to or greater than that of the dopant in first phosphorescent layer 251. First functional layer 252 may be made from a contemporary hole transport material, for example, an oxadiazole compound having amino substituent, a triphenylmethane compound having amino substituent, a tertiary compound, a hydazone compound, a pyrazoline compound, an enamine compound, a styryl compound, a stilbene compound, or a carbazole compound. First functional layer 252 may have a highest occupied molecular orbital (HOMO) energy level ranging from 5.2 eV to 6.2 eV, and a lowest unoccupied molecular orbital (LUMO) energy level ranging from 2.0 eV to 3.0 eV.

In addition, second functional layer 254 that can prevent an energy transfer without interfering with the diffusion of triplet excitons between blue fluorescent layer 253 and second phosphorescent layer 255 may be formed between blue fluorescent layer 253 and second phosphorescent layer 255. Here, second functional layer 254 has a band gap energy that is greater than that of the dopant in blue fluorescent layer 253, and a triplet energy that is equal to or less than that of the host of blue fluorescent layer 253 and equal to or higher than that of the dopant in second phosphorescent layer 255.

Second functional layer 254 may be made from a contemporary electron transport material, for example, an anthracene compound, a phenanthracene compound, a pyrene compound, a perylene compound, a chrysene compound, a triphenylene compound, a fluoranthene compound, a periflanthene compound, an azole compound, a diazole compound, or a vinylene compound. Meanwhile, second functional layer 254 may have a HOMO energy level ranging from 5.5 eV to 7.0 eV, and a LOMO energy level ranging from 2.5 eV to 3.5 eV.

First and second functional layers 252 and 254 do not interfere with the diffusion of triplet excitons while preventing the energy transfer between the light emitting layers, and at the same time, restrict the electrons and holes to be in blue fluorescent layer 253 so as to maximize the charge balance.

Table 1 below shows a comparison between the structure and materials of a contemporary white OLED (fluorescent layer-fluorescent layer-phosphorescent layer, FFP) and a white OLED (phosphorescent layer-fluorescent layer-phosphorescent layer, PFP) according to the second exemplary embodiment, which are fabricated in order to test the performance of the white OLED of the second exemplary embodiment.

TABLE 1

| | | | Second Exemplary | Thickness or |
|---|---|---|---|---|
| | | Prior Art (FFP) | embodiment (PFP) | Doping % |
| Cathode | | Al | Al | 1500 Å |
| Electron Injection Layer (EIL) | | LiF | LiF | 6 Å |
| Electron Transporting Layer (ETL) | | bis(2-methyl-8-quinolinolato)- | Balq | 400 Å |
| | | 4-phenylphenolato- | | |
| | | aluminum | | |
| | | (Balq) | | |
| RED | Emission Type | Phosphorescence | Phosphorescence | |
| Layer | Host | Balq | Balq | 50 Å |
| | Dopant | Ir(piq)2(acac) | Ir(piq)2(acac) | 2% |
| (2nd) Functional Layer | | Balq | Balq | 50 Å |
| BLUE Layer | Emission Type | Fluorescence | Fluorescence | |
| | Host | TcTa | TcTa | 50 Å |
| | Dopant | BPTA | BPTA | 12% |
| (1st) Functional Layer | | CBP | CBP | 40 Å |
| Green Layer | Emission Type | Fluorescence | Phosphorescence | |
| | Host | TcTa | TcTa | 150 Å |
| | Dopant | C545T | Ir(ppy)3 | 2% |

| | | | |
|---|---|---|---|
| Hole Transporting Layer (HTL) | 4,4′-bis-[N-(1-naphthyl)- | 4,4′-bis-[N-(1-naphthyl)- | 100 Å |
| | N-phenylamino]- | N-phenylamino]- | |
| | bi-phenyl (NPB) | bi-phenyl | |
| | | (NPB) | |
| Hole Injection Layer (HIL) | 4,4,4-tris(3- | 4,4,4-tris(3- | 500 Å |
| | methylphenylphenylamino)- | methylphenylphenylamino)- | |
| | triphenylamine) | triphenylamine | |
| | (m-MTDATA) | (m-MTDATA) | |
| Anode | ITO | ITO | 500 Å |

The contemporary white OLED has the FFP structure, and the white OLED of the second exemplary embodiment has the PFP structure. In the fabrication of the contemporary white OLED, a functional layer is interposed between a red layer which is a phosphorescent layer, and a blue layer which is a fluorescent layer; and the blue layer and a green layer, both of which are fluorescent layers, contact each other. Meanwhile, in the fabrication of the white OLED of the second exemplary embodiment, a red layer and a green layer, which are phosphorescent layers, are disposed on both sides of a blue layer that is a fluorescent layer, respectively, and the first and second functional layers are interposed between the blue layer and the red layer and the blue layer and the green layer, respectively.

Table 2 shows experimental results of light emitting characteristics of the two white OLEDs described in Table 1 at 4,000 nit (1 candela per square metre (cd/m²)=1 nit).

TABLE 2

| | | | Efficiency | External | Power |
|---|---|---|---|---|---|
| | CIE @ 4,000 nit | | (cd/A)@ | QE(%)@ | Efficiency |
| OLED | x | y | 4,000 nit | 4,000 nit | (lm/w) |
| FFP | 0.33 | 0.33 | 16 | 9 | 5.05 |
| PFP | 0.32 | 0.35 | 20 | 11 | 6.1 |

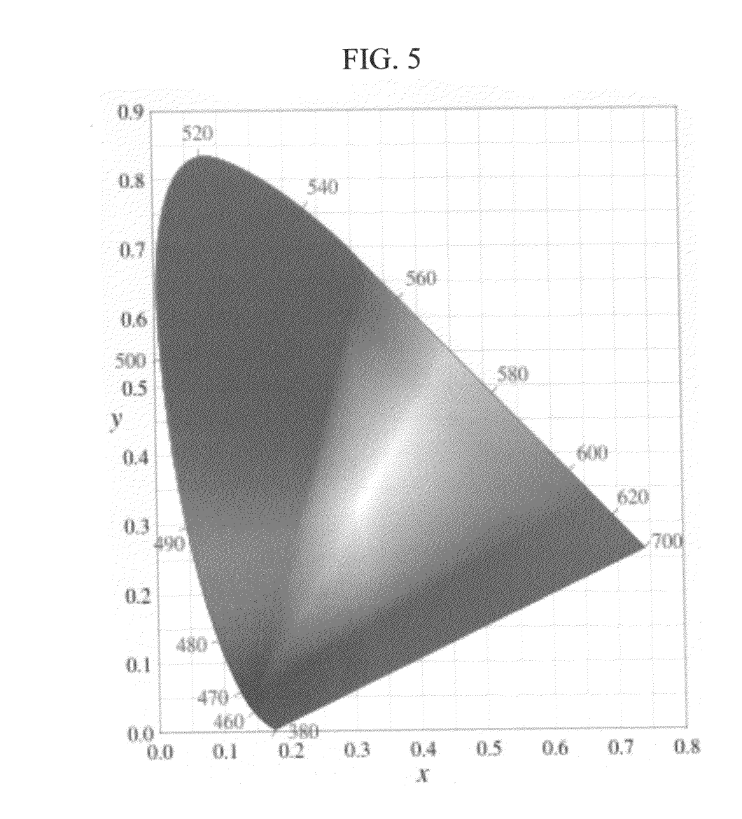

FIG. 5 shows a CIE 1931 color space chromaticity diagram. Commission internationale de l'eclairage (CIE) system is used to characterize colors by two color a luminance parameter Y and two coordinates x and y which specify the point on a CIE 1931 color space chromaticity diagram. The CIE 1931 color space is the first mathematically defined color space created by the international Commission on Illumination (CIE) in 1931.

According to the above Table 2, a Commission internationale de l'eclairage (CIE) coordinate of the contemporary white OLED (FFP) is (0.33, 0.33), and the CIE coordinate of the white OLED (PFP) of the second exemplary embodiment is (0.32. 0.35); and thus, both of the contemporary white OLED (FFP) and the white OLED (PFP) of the second exemplary embodiment, have white spectrums. Here, the white OLED (PFP) of the second exemplary embodiment shows a high light emitting efficiency with a small color change. In particular, the light emitting efficiency of the contemporary white OLED (FFP) was 16 candela/ampere (cd/A); however, the light emitting efficiency of the white OLED (PFP) of the second exemplary embodiment greatly increased to 20 (cd/A). In addition, an external quantum efficiency of the contemporary white OLED (FFP) was 9%, and the external quantum efficiency of the white OLED (PFP) of the second exemplary embodiment was 11%. Also, a power efficiency of the contemporary white OLED (FFP) was 5.05 lumen/watt (lm/w), and the power efficiency of the white OLED (PFP) of the second exemplary embodiment greatly increased to 6.1 lm/w.

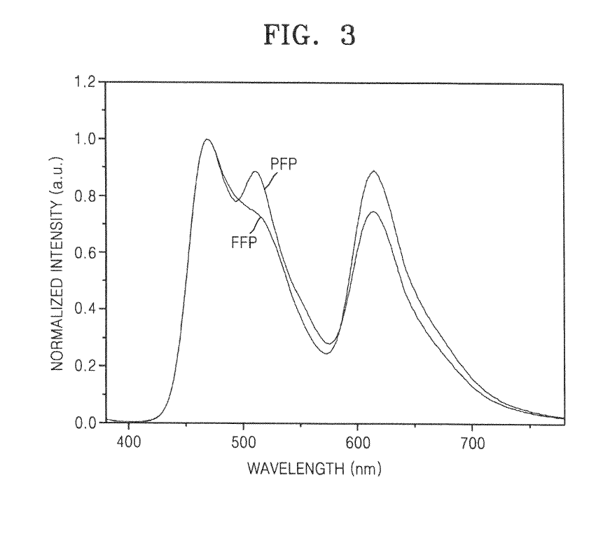

FIG. 3 shows light emitting spectrums of the contemporary white OLED (FFP) and the white OLED (PFP) of the second exemplary embodiment. Referring to FIG. 3, the white OLED (PFP) of the second exemplary embodiment shows a peak at the green wavelength region (around 510 nm), and has a greater green light emitting than that of the contemporary white OLED. Therefore, the triplet excitons of the blue host are diffused to the green dopant in the white OLED (PFP) of the second exemplary embodiment, and thus, the white OLED (PFP) of the second exemplary embodiment has an excellent light emitting efficiency.

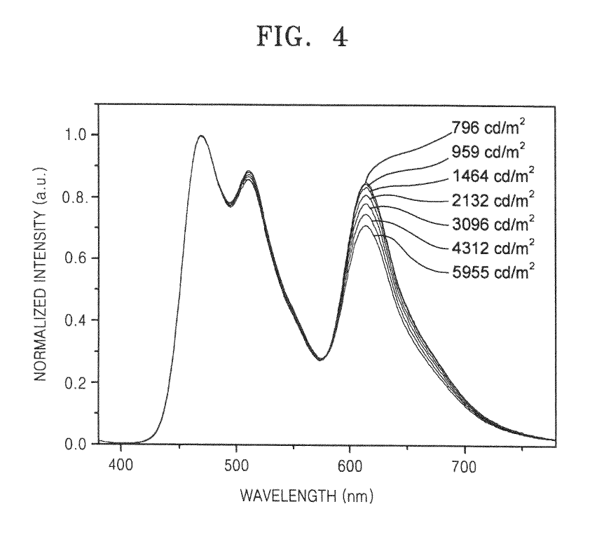

FIG. 4 shows light emitting spectrums at different brightness of the white OLED (PFP) of the second exemplary embodiment, described in Table 1. Referring to FIG. 4, the changes in the spectrums according to the changes in brightness are small. This property is essential for a display device, and thus, an exciton profile can be maintained stably even when an electric field changes.

While a few example embodiments have been particularly shown and described with reference to exemplary embodiments thereof, it will be understood by those of ordinary skill in the art that various changes in form and details may be made therein without departing from the spirit and scope of the exemplary embodiment as defined by the following claims.

What is claimed is:

1. A white organic light emitting device (OLED), comprising:
a first phosphorescent layer comprising a first host material and a first dopant;
a blue fluorescence layer comprising a blue host material and a blue dopant, and disposed on the first phosphorescent layer; and
a second phosphorescent layer comprising a second host material and a second dopant, and disposed on the blue fluorescence layer, with a triplet energy of the blue host material of the blue fluorescence layer being greater than both of a triplet energy of the first dopant of the first phosphorescent layer and a triplet energy of the second dopant of the second phosphorescent layer.

2. The white OLED of claim 1, comprised of the first host material of the first phosphorescent layer having a hole transport property.

3. The white OLED of claim 1, comprised of the second host material of the second phosphorescent layer having an electron transport property.

4. The white OLED of claim 1, further comprising a first functional layer disposed between the blue fluorescence layer and the first phosphorescent layer, and having a band gap energy that is greater than that of the blue dopant of the blue fluorescence layer, and a triplet energy that is equal to or lower than that of the blue host material of the blue fluorescence layer, and that is equal to or higher than that of the first dopant of the first phosphorescent layer.

5. The white OLED of claim 4, comprised of the first functional layer having a highest occupied molecular orbital (HOMO) energy level ranging from approximately 5.2 eV to 6.2 eV, and a lowest unoccupied molecular orbital (LUMO) energy level ranging from approximately 2.0 eV to 3.0 eV.

6. The white OLED of claim 1, further comprising a second functional layer formed between the blue fluorescence layer and the second phosphorescent layer, and having a band gap energy that is greater than that of the blue dopant of the blue fluorescence layer, and a triplet energy that is equal to or lower than that of the blue host material of the blue fluorescence layer, and that is equal to or higher than that of the second dopant of the second phosphorescent layer.

7. The white OLED of claim 6, comprised of the second functional layer having a highest occupied molecular orbital (HOMO) energy level ranging from approximately 5.5 eV to 7.0 eV, and a lowest unoccupied molecular orbital (LUMO) energy level ranging from approximately 2.5 eV to 3.5 eV.

8. The white OLED of claim 7, comprised of the HOMO energy level of the second functional layer being equal to or higher than that of the blue fluorescence layer, the first phosphorescent layer, and the second phosphorescent layer.

9. The white OLED of claim 6, comprised the HOMO energy level of the second functional layer being equal to or higher than that of the blue fluorescence layer, the first phosphorescent layer, and the second phosphorescent layer.

10. The white OLED of claim 1, further comprising:
a first functional layer disposed between the blue fluorescence layer and the first phosphorescent layer, and having a band gap energy that is greater than that of the blue dopant of the blue fluorescence layer, and a triplet energy level that is equal to or lower than that of the blue host material of the blue fluorescence layer, and that is equal to or higher than that of the first dopant of the first phosphorescent layer; and
a second functional layer disposed between the blue fluorescence layer and the second phosphorescent layer, and having a band gap energy that is greater than that of the blue dopant of the blue fluorescence layer, and a triplet energy level that is equal to or lower than that of the blue host material of the blue fluorescence layer, and that is equal to or higher than that of the second dopant of the second phosphorescent layer,
with the first and second functional layers having band gaps, which do not absorb a light emitting spectrum of the blue dopant of the blue fluorescence layer.

11. The white OLED of claim 10, comprised of the first functional layer having a highest occupied molecular orbital (HOMO) energy level ranging from approximately 5.2 eV to 6.2 eV, and a lowest unoccupied molecular orbital (LUMO) energy level ranging from approximately 2.0 eV to 3.0 eV.

12. The white OLED of claim 11, comprised of the second functional layer having a highest occupied molecular orbital (HOMO) energy level ranging from approximately 5.5 eV to 7.0 eV, and a lowest unoccupied molecular orbital (LUMO) energy level ranging from approximately 2.5 eV to 3.5 eV.

13. The white OLED of claim 10, comprised of the second functional layer having a highest occupied molecular orbital (HOMO) energy level ranging from approximately 5.5 eV to 7.0 eV, and a lowest unoccupied molecular orbital (LUMO) energy level ranging from approximately 2.5 eV to 3.5 eV.
